(19) United States
(12) Patent Application Publication
(10) Pub. No.: US 2026/0305345 A1
(43) Pub. Date: Oct. 1, 2026

(54) MICRO-ELECTRO MECHANICAL SYSTEM DEVICE STRUCTURE AND SEMICONDUCTOR STRUCTURE

(71) Applicant: TAIWAN SEMICONDUCTOR MANUFACTURING COMPANY LTD., HSINCHU (TW)

(72) Inventor: YU-HSUN LI, YUNLIN COUNTY (TW)

(21) Appl. No.: 19/090,463

(22) Filed: Mar. 26, 2025

(51) Int. Cl. H10W 40/47; H02N 1/00

(52) U.S. Cl. CPC H10W 40/47; H02N 1/008

(57) ABSTRACT

A micro-electro mechanical system (MEMS) device structure is provided. The MEMS device structure includes a frame structure defining a region; a support structure coupled with the frame structure, the support structure comprises a plurality of blocks laterally arranged within the region from a cross-sectional view perspective; and a cap structure over the support structure. The cap structure includes a first cap disposed over the support structure and a protrusion of the first cap spans at least a first block; and a second cap disposed over the support structure and a protrusion of the second cap spans at least a second block. A first distance between the protrusion of the first cap and the first block is different from a second distance between the protrusion of the second cap and the second block. A semiconductor structure is also provided.

### BACKGROUND

Micro-electro mechanical system (MEMS) devices have been recently developed and are commonly utilized in electronic equipment. The MEMS device is a micro-sized device, usually between less than 1 micron and several millimeters in size. The MEMS device is fabricated using semiconductive materials to form mechanical and electrical features. The MEMS device may include a number of elements (e.g., stationary or movable elements) for achieving electro-mechanical functionality. MEMS devices are widely used in various applications, such as motion sensors, pressure sensors, printer nozzles, inertial sensors, accelerometers, and gyroscopes. Moreover, MEMS applications are extended to optical applications, such as movable mirrors, and radio frequency (RF) applications, such as RF switches or the like.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a MEMS device structure according to some embodiments of the present disclosure.

FIG. 2 illustrates a top view of a portion of a cap structure according to some embodiments of the present disclosure.

FIG. 3 illustrates a cross-sectional view of a cap structure according to some embodiments of the present disclosure.

FIG. 4A illustrates a cross-sectional view of a MEMS device structure according to some embodiments of the present disclosure.

FIG. 4B illustrates a cross-sectional view of a MEMS device structure according to some embodiments of the present disclosure.

FIG. 5A illustrates a cross-sectional view of a MEMS device structure according to some embodiments of the present disclosure.

FIG. 5B illustrates a cross-sectional view of a MEMS device structure according to some embodiments of the present disclosure.

FIG. 6A illustrates a top view of a MEMS device structure according to some embodiments of the present disclosure.

FIG. 6B illustrates a top view of a MEMS device structure according to some embodiments of the present disclosure.

FIG. 7 illustrates a cross-sectional view of a MEMS device structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” "on" and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as "first", "second" and "third" describe various elements, components, regions, layers and/or sections, these elements, components, regions, layers, and/or sections should not be limited by these terms. These terms may be only used to distinguish one element, component, region, layer, or section from another. The terms such as "first", "second", and "third" when used herein do not imply a sequence or order unless clearly indicated by the context.

In some semiconductor manufacturing processes, there may be a need to cool the semiconductor structures. As the semiconductor industry continues to push the boundaries of miniaturization and performance, effective heat management has become increasingly important.

In some examples, semiconductor wafers can be cooled using a method known as back cooling, which is achieved by cooling the back of the wafer (i.e., the non-active surface). For example, in the method of liquid back cooling, the liquid coolant directly or indirectly contacts the back of the wafer, rapidly transferring the heat generated by the wafer to the liquid coolant. Through a circulating cooling system, the liquid coolant is sent to a cooler for cooling and then flows back to the wafer, forming a closed cooling cycle. Liquid coolants can possess good thermal conductivity, chemical stability, and are usually neutral liquids with a larger specific heat capacity. Examples of liquid coolants include water, mixtures of water and ethylene glycol, and organic coolants.

In other examples, for localized cooling, direct liquid cooling (DLC) methods can be employed. This approach allows a cooling structure to come into direct contact with the object to be cooled, typically used for major heat-generating components such as CPUs and GPUs. In some instance, a cooling plate equipped with cooling liquid can be in direct contact with the surface of the object that requires cooling.

Immersion cooling is a method that utilizes a single-phase liquid coolant in direct contact with the object being cooled, as the object is fully or partially submerged in the liquid coolant, allowing for effective heat removal. In examples where immersion cooling is employed for heat dissipation, the liquid coolant may possess sufficiently low electrical conductivity and low corrosiveness to prevent damage to the object being cooled.

In semiconductor manufacturing processes that the immersion cooling method is utilized, the semiconductor wafers can be arranged within a cooling tank where a liquid coolant, such as water or other nonconductive liquid, is continuously injected. The semiconductor wafers are submerged in the liquid coolant, allowing heat to transfer from the semiconductor wafers to the liquid coolant (e.g., normal water at room temperature or lower). As the liquid coolant absorbs heat from the semiconductor wafers, the heated liquid coolant (e.g., warm water) can be withdrawn from the cooling tank.

In order to improve the efficiency of the immersion cooling method, several strategies can be employed, such as selecting the right liquid coolant, optimizing the dynamics of the liquid coolant, and enhancing heat transfer. In detail, in the strategy of enhancing immersion cooling efficiency by selecting the right liquid coolant, the thermal properties of the coolant—such as its heat capacity, thermal conductivity, and viscosity—are related to heat transfer efficiency. Generally, a liquid coolant with higher thermal conductivity can absorb and dissipate heat more effectively, leading to improved cooling performance. Additionally, the choice of coolant should consider factors such as non-conductivity, environmental impact, and compatibility with electronic components to prevent any adverse reactions.

Another aspect of improving immersion cooling efficiency is the design of the cooling system itself, which should optimize the dynamics of the liquid coolant and/or enhance heat transfer accordingly. For example, optimizing the arrangement of electronic components within the cooling tank can facilitate better fluid flow and heat distribution. By ensuring that the liquid coolant circulates effectively around the components in the cooling tank, the cooling results can be enhanced. Implementing features such as baffles or flow guides can help direct the coolant flow, ensuring that it reaches most of the areas of the cooling system uniformly.

In some comparative embodiments, the components in the cooling tank, such as semiconductor structures, cannot be sufficiently cooled by merely being directly placed in the cooling tank. In these embodiments, the components, such as semiconductor wafers, can be arranged in a line, one by one, with their main surfaces facing each other. Although the liquid coolant may pass through the spaces between each pair of adjacent semiconductor wafers to cool them; however, since the spaces between each pair of adjacent semiconductor wafers are limited and lack sufficient mechanisms for optimizing the dynamics of the liquid coolant, the cooling results are still quite limited.

Therefore, in some embodiments of the present disclosure, a heat dissipation structure can be placed with the components (e.g., semiconductor wafers) in the cooling tank to improve immersion cooling efficiency. In some embodiments, the heat dissipation structure may actively or passively enhance fluid flow force for cooling the components in the cooling tank. Accordingly, the cooling of the semiconductor structures can be implemented more efficiently, thereby maintaining the performance of the semiconductor structures.

Moreover, the heat dissipation structure in some embodiments of the present disclosure can be a micro-electro mechanical system (MEMS) device structure. The fabrication of such MEMS structures can be compatible with semiconductor processes, and their dimensions can be compatible with those of semiconductor wafers. Furthermore, the MEMS device structure can correspond to structures on semiconductor wafers to provide a more suitable heat dissipation mechanism or connection relationship. In some embodiments, the heat dissipation structure may have irregular or regular protrusions of varying heights to induce turbulence in the liquid coolant flowing through, thereby improving the efficiency of heat removal from the semiconductor wafers. In some embodiments, the heat dissipation structure with higher protrusions, when combined with the actuation of MEMS electrodes, can drive a larger flow of liquid coolant compared to structures with lower protrusions, thus enhancing the efficiency of heat removal from the semiconductor structures and achieving better cooling results.

Referring to FIG. 1, which illustrates a MEMS device structure 10 according to some embodiments of the present disclosure. In some embodiments, the MEMS device structure 10 includes a frame structure 102, a support structure 104, and a cap structure 106. The frame structure 102 is a connection structure configured to be in contact with the semiconductor wafers or other structures to be cooled, while the other portions of the MEMS device structure 10 can be suspended over the semiconductor wafers or the structures to be cooled (e.g., over a first side 80A of a semiconductor structure 80). In some embodiments, the frame structure 102 can be fixed over the semiconductor structure 80 using an adhesion glue 108. In other words, using the semiconductor structure 80 as an example, the MEMS device structure 10 can be a removable structure for the semiconductor structure 80 during the cooling operations, and the removal of the adhesion glue 108 can detach the MEMS device structure 10 from the first side 80A of the semiconductor structure 80. In some embodiments, the frame structure 102 may define a region 103 that is intended to be cooled using the MEMS device structure 10. Therefore, the location of the MEMS device structure 10 can be related to the region of the semiconductor structure 80 that is particularly to be cooled.

In some embodiments, the semiconductor structure 80 can include a substrate 81 (e.g., a PCB) and a plurality of semiconductor components 82 disposed thereon. In some embodiments, the semiconductor components 82 may include components that have a higher operating temperature, such as memory structures (e.g., HBMs, SRAMs, DRAMs, etc.), or components that require a more stable operating temperature, such as silicon photonic ICs. These semiconductor components 82, in the form of dies, chips, or modules, can be disposed on the substrate 81 for cooling by the MEMS device structure 10. In some embodiments, one MEMS device structure 10 may be used to cool more than one semiconductor component 82 on the substrate 81, depending on the sizes of the MEMS device structure 10 and the semiconductor components 82.

In some embodiments, the frame structure 102 may include an outer frame 102A in proximity to the edges of the MEMS device structure 10 and an inner frame 102B enclosed by the outer frame 102A. The adhesion glue 108 is in contact with the bottom portion of the outer frame 102A, and the inner frame 102B is connected to the outer frame 102A through a metal connection structure (e.g., a metal spring 130 or suitable elastic component, simplified as shown in the figure). In some embodiments, the inner frame 102B may be referred to as the middle frame, as it is positioned between the outer frame 102A of the frame structure 102 and other structures of the MEMS device structure 10. In some embodiments, the inner frame 102B is suspended over the semiconductor structure 80, like the support structure 104 and the cap structure 106 of the MEMS device structure 10. In some embodiments, the material of the frame structure 102 includes semiconductor materials such as silicon (Si). In some embodiments, the material of the frame structure 102 includes metal and can be further coated with insulation material for immersion cooling.

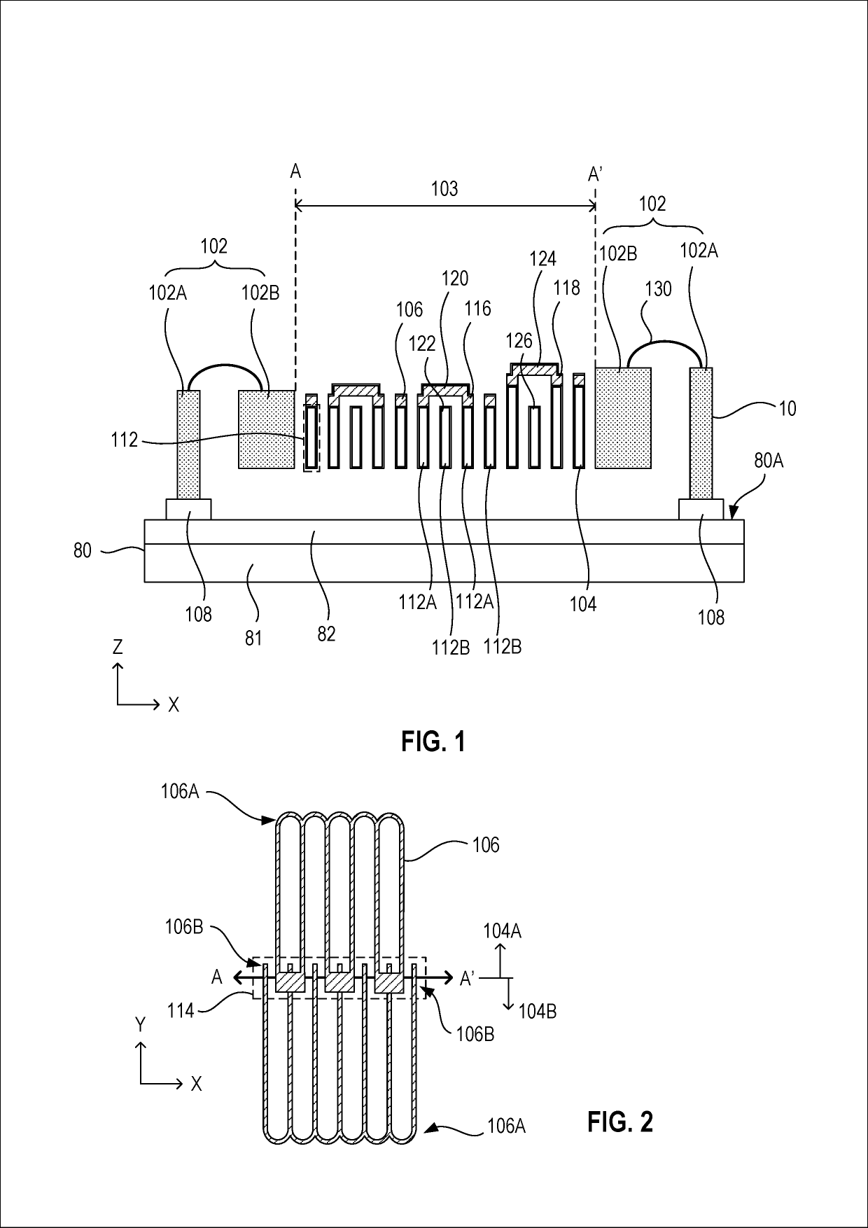

Referring to FIG. 2, which is a top view of a portion of the cap structure 106 according to some embodiments of the present disclosure, and the cross-sectional view of the cap structure 106 illustrated in FIG. 1 is the cross-sectional view of the cap structure 106 along a line AA' in FIG. 2. As shown in FIGS. 1 and 2, the cap structure 106 and the support structure 104 below the cap structure 106 is a series on interdigitated fingers, each of which is fixed at one end (e.g., an end 106A) and is free at the other end (e.g., an end 106B). The free ends of the interdigitated fingers extend over, in other words are cantilevered over the region defined by the frame structure 102. The size, number, and placement of the support structure 104 are for illustration and any number size and placement of support structure 104 is contemplated within the present disclosure. As will be addressed in more detail below, the support structure 104 includes a plurality of movable elements that may be formed by patterning a wafer into the desired patterns. In some embodiments, the material of the support structure 104 includes semiconductor material. In such embodiments, the support structure 104 may include silicon (Si), such as polysilicon. In some embodiments, the support structure 104 may include piezoelectric materials such as quartz (SiO₂), lead zirconate titanate (PZT), polyvinylidene fluoride (PVDF), barium titanate (BaTiO₃), aluminum nitride (AlN), or the like. The piezoelectric material-based support structure 104 may provide active control over the vibrating direction of the support structure 104. In some embodiments, the support structure 104 substantially referred to as a comb structure.

As shown in FIG. 1, in some embodiments, the support structure 104 is coupled with the frame structure 102. The support structure 104 may include a plurality of blocks 112 laterally arranged within the region 103 from the cross-sectional view perspective. As aforementioned, the plurality of blocks 112 can be seen from the view cutting through the interdigitated fingers of the support structure 104. Accordingly, the blocks 112 illustrated in FIG. 1 can be further divided into a plurality of blocks 112 cut from fingers in proximity to a first side 104A (labeled in FIG. 2) of the support structure 104 (e.g., blocks 112A) and a plurality of blocks 112 cut from fingers in proximity to a second side 104B (labeled in FIG. 2) of the support structure 104 (e.g., blocks 112B). The first side 104A is opposite to the second side 104B. In some embodiments, since the fingers in the support structure 104 are arranged in an interdigitated manner (e.g., within an interdigitated region 114 shown in FIG. 2), the vibrations of the fingers in proximity to different sides of the support structure 104 may exhibit a complex motion, potentially involving multiple directions. For instance, in some examples, the blocks 112A shown in FIG. 1 may have a vibration direction different from that of the blocks 112B and therefore a movement in the opposite direction can be generated.

The cap structure 106 is disposed over the support structure 104 and performed as the electrodes of the MEMS device structure 10. In some embodiments, the material of the cap structure 106 include metals such as gold (Au), silver (Ag), copper (Cu), aluminum (Al), or the like. Typically, the cap structure 106 can be formed over each of the fingers of the support structure 104 and therefore can be seen over each of the blocks 112 in the cross-sectional view perspective shown in FIG. 1. In some alternative embodiments, an upper surface of the cap structure 106 is substantially leveled with an upper surface of the frame structure 102, or the upper surface of the cap structure 106 over each blocks 112 is substantially leveled with each other. However, in some embodiments of the present disclosure, a portion of the cap structure 106 may have an upper surface higher than that of other portions of the cap structure 106, or higher than that of a portion of the frame structure 102. In other words, without considering the spaces between each part of the cap structure 106, in some embodiments of the present disclosure, the upper profile of the cap structure 106 can be generally uneven.

As shown in FIG. 1, in some embodiments, the cap structure 106 includes at least a first cap 116 and at least a second cap 118. The first cap 116 is disposed over the support structure 104 and a protrusion 120 of the first cap 116 spans at least a first block 122 of the support structure 104. The second cap 118 is disposed over the support structure 104 and a protrusion 124 of the second cap 118 spans at least a second block 126 of the support structure 104. That is, the cap structure 106 may have one or more protrusions that is disposed on two different blocks and spans one or more blocks. In the embodiment that each cap spans a single block, a width of the protrusion 120 is substantially identical to a width of the protrusion 124.

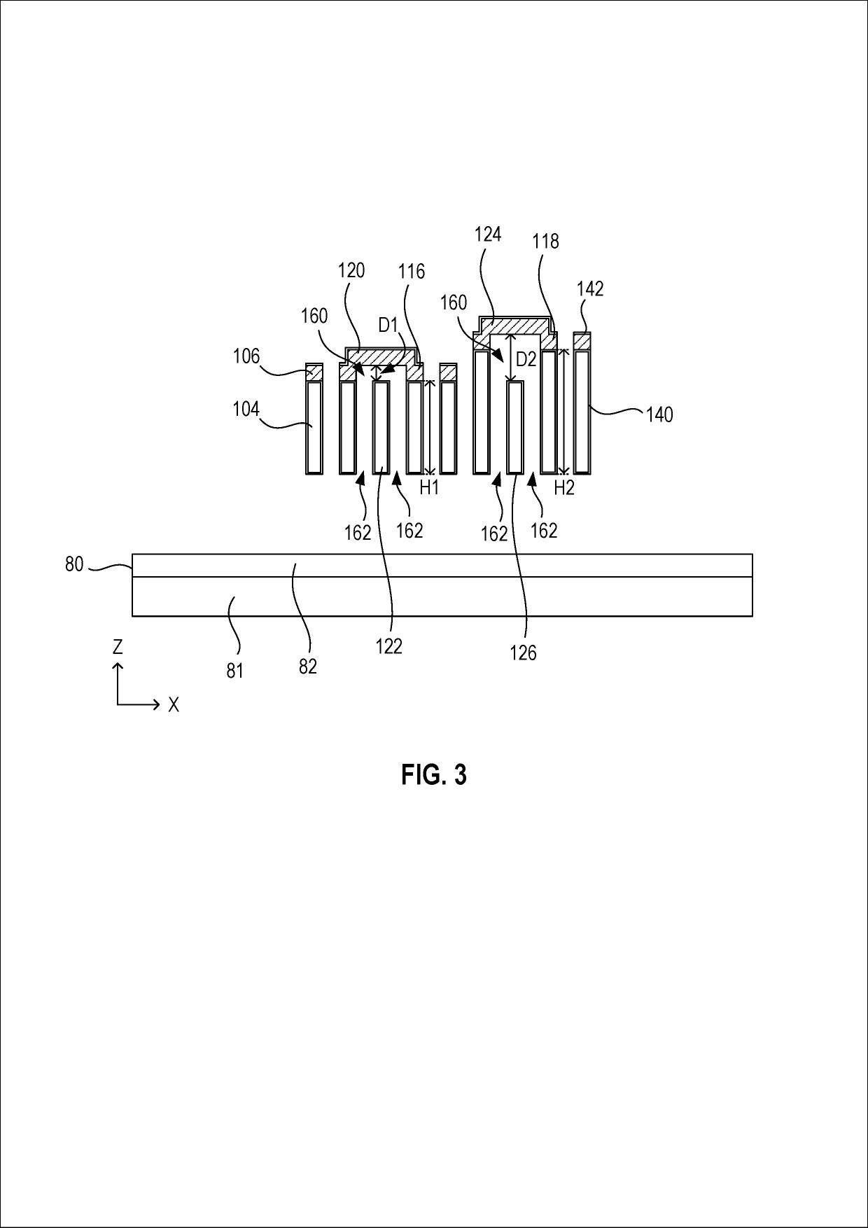

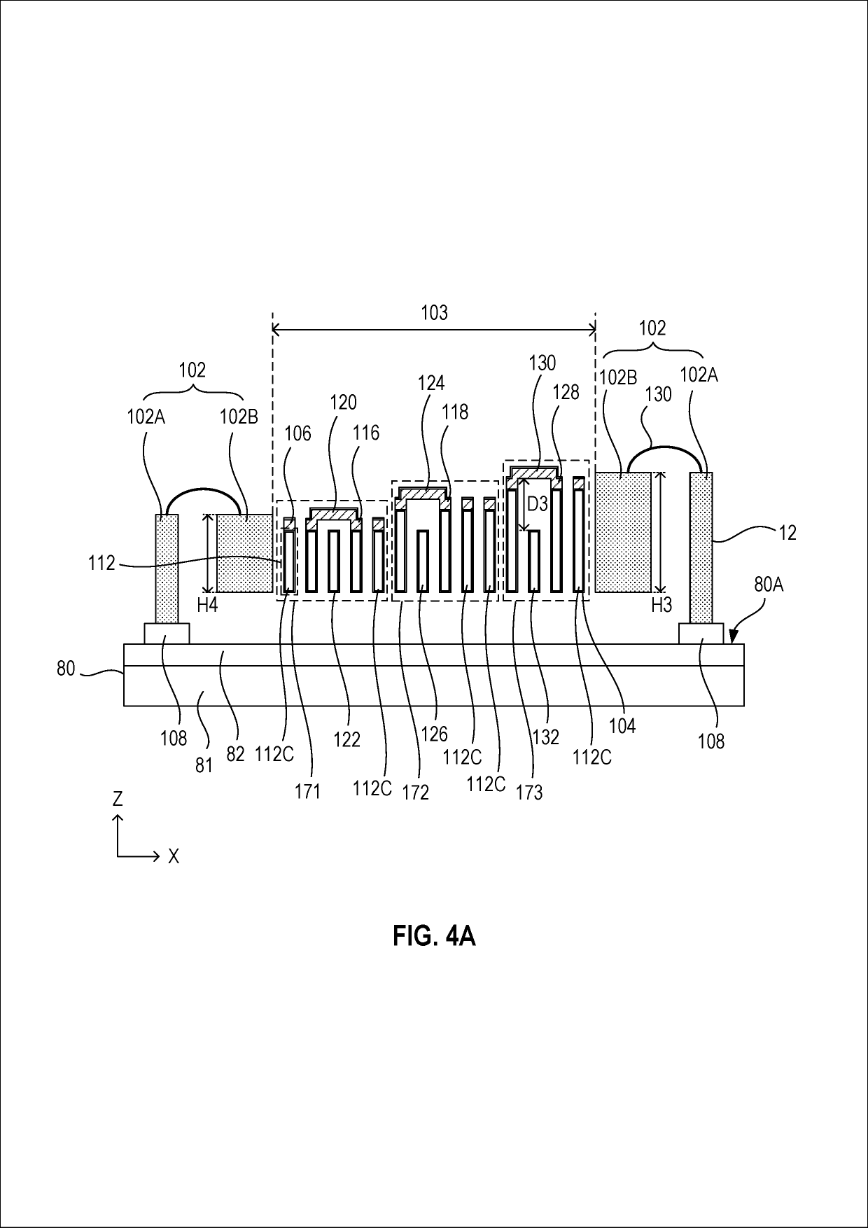

Accordingly, referring to FIG. 3, which is enlarged from the region 103 shown in FIG. 1, since the one or more blocks is spanned by the protrusion of the cap structure 106, the cap (e.g., the second cap 118 having the protrusion 124) and the blocks below the cap may substantially provide a chamber structure 160 having several openings 162 (e.g., the spaces between the blocks of the support structure 104) can be implemented as a flow channel. That is, the MEMS device structure in some embodiments of the present disclosure includes a plurality of flow channels including a space (i.e., the chamber structure 160) between the caps and the blocks of the support structure 104 spanned by the caps, and each of the flow channels are connected with a space (i.e., the openings 162) between two adjacent blocks of the support structure 104. Moreover, in some embodiments, a first distance D1 between the protrusion 120 (i.e., a bottom surface of the protrusion 120) of the first cap 116 and the first block 122 (i.e., a top surface of the first block 122) of the support structure 104 is different from a second distance D2 between the protrusion 124 (i.e., a bottom surface of the protrusion 124) of the second cap 118 and the second block 126 (i.e., a top surface of the second block 126) of the support structure 104.

As shown in FIG. 3, the first cap 116 and the second cap 118 are bonded to different portions of the support structure 104. For example, the first cap 116 is bonded to a first pair of blocks of the support structure 104, while the second cap 118 is bonded to a second pair of blocks of the support structure 104. Furthermore, in some embodiments, a height H1 of the first pair of blocks of the support structure 104 is less than a height H2 of the second pair of blocks. In other words, the second cap 118, elevated by the support structure 104, is raised substantially by extending a portion of the length of the support structure 104 (i.e., the support structure 104 that bonded to the second cap 118). It can also be said that the second cap 118 is formed over the portion of the support structure 104 that has a taller structure (i.e., the blocks of greater height from the cross-sectional view perspective).

In some embodiments, the first distance D1 between the protrusion 120 of the first cap 116 and the first block 122 of the support structure 104 is in a range from about 2 μm to about 6 μm. In some embodiments, the second distance D2 between the protrusion 124 of the second cap 118 and the second block 126 of the support structure 104 is in a range from about 6 μm to about 30 μm. In some embodiments, the lower limit of the range of the second distance D2 is associated with the ability to create sufficient turbulence for enhancing heat removal efficiency, while the upper limit of the range of D2 is determined by the physical limitations of the support structure 104. For instance, if the second distance D2 exceeds approximately 30 μm, the support structure 104, designed to elevate the caps with protrusions, may collapse.

That is, to enhance the efficiency of heat removal from semiconductor structure 80 in the immersion cooling method, some embodiments of the present disclosure employ caps with protrusions, particularly taller protrusions elevated by higher blocks of the support structure 104 (referred to as the "elevated structure"). These elevated protrusions may create turbulence in the liquid coolant within the cooling tank, which enhances heat removal efficiency and improves cooling performance.

In some embodiments, the surfaces of the support structure 104 and the cap structure 106 are coated with a conformal, pinhole-free insulation material such as oxide, parylene, or the like. For instance, as shown in FIG. 3, each of the blocks of the support structure 104 can be surrounded by a first oxide layer 140. The first oxide layer 140 can be formed or deposited on the surfaces of the support structure 104 after it is fabricated and suspended. Subsequently, the four sides of the blocks of the support structure 104 may in contact with the deposition material or undergo oxidation in an oxidation process for forming the first oxide layer 140. In some embodiments, the upper surface of the cap structure 106 can be covered by a second oxide layer 142. The second oxide layer 142 can be deposited on the upper surface of the cap structure 106 through a deposition process. Since the interdigitated fingers in the MEMS device structure 10 (i.e., the cap structure 106 and the support structure 104 below the cap structure 106) will vibrate during the cooling operation, the relatively soft material, i.e., the metal-made cap structure, can be structurally enhanced by being covered with the second oxide layer 142 to prevent deformation. On the other hand, the second oxide layer 142 may reduce the exposure of the cap structure 106 and mitigate the corrosion that may be caused by the cooling liquid.

The elevated structure of the protrusion may form a larger chamber, substantially enclosed by the protrusion of the cap structure 106, the cap itself, and the blocks below it. Because the protrusion is elevated, a greater volume of liquid coolant can accumulate within this larger chamber. That is, the volume of a first flow channel substantially enclosed by the protrusion 120 and the support structure 104 is different from (e.g., less than) a volume of a second flow channel substantially enclosed by the protrusion 124 and the support structure 104. By using the flow channel having greater volume, the increased volume of liquid coolant can then be pumped out through the spaces between the adjacent blocks of the support structure 104, generating turbulence that further enhances heat removal efficiency.

In other words, the comb-typed electrodes (i.e., the cap structures over the comb-typed support structures) in some embodiments of the present disclosure may feature one or more protrusions on some electrodes, spanning over interdigitated electrodes. In some embodiments, one of the blocks spanned by the protrusion and the two of the blocks bonded to the cap structure belongs to different comb electrodes of the MEMS device structure. These protrusions, with their elevated structure, create an uneven profile (disregarding the spaces between the comb-typed support structures) of the MEMS device structure, which induces turbulence in the liquid coolant within the cooling tank during the immersion cooling process. Furthermore, the elevated structure provides a larger chamber under the protrusion, allowing a greater volume of liquid coolant to be pumped out during electrode vibrations. This process generates additional turbulence in the liquid coolant, further enhancing the efficiency of heat removal from the object to which the MEMS device structure is attached (e.g., semiconductor wafers) during immersion cooling.

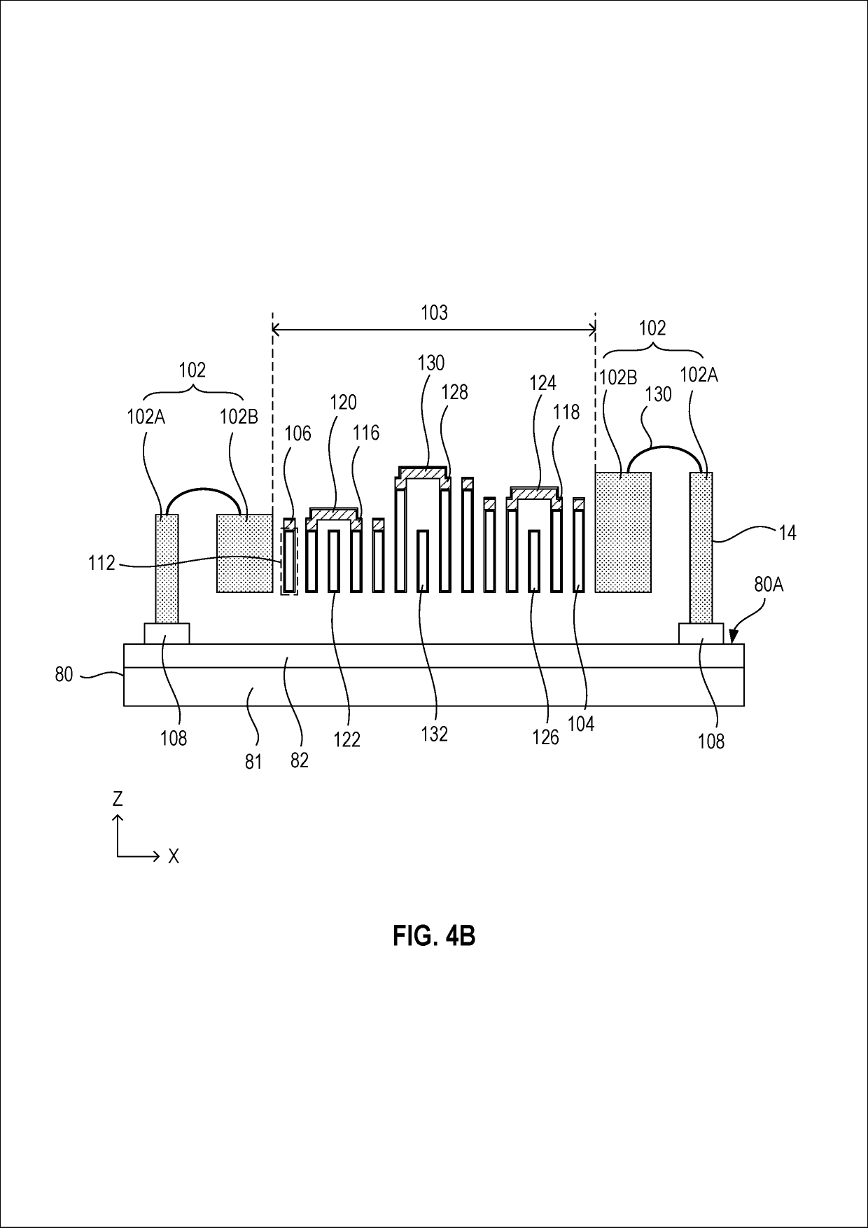

Referring to FIG. 4A, in some embodiments, the cap structure 106 of a MEMS device structure 12 further comprises a third cap 128 disposed over the support structure 104 and a protrusion 130 of the third cap 128 spans at least a third block 132 of the support structure 104. In some embodiments, the third distance D3 between the protrusion 130 (i.e., a bottom surface of the protrusion 130) of the third cap 128 and the third block 132 (i.e., a top surface of the third block 132) of the support structure 104 is greater than the second distance D2 (labeled in FIG. 3) between the protrusion 124 of the second cap 118 and the second block 126 of the support structure 104. In some embodiments, the second distance D3 between the protrusion 130 of the third cap 128 and the third block 132 of the support structure 104 is in a range from about 6 μm to about 30 μm.

In the embodiment shown in FIG. 4A, the first distance D1 (labeled in FIG. 3), the second distance D2 (labeled in FIG. 3), and the third distance D3 are arranged to be increased gradually between two sides of the region 103 defined by the frame structure 102. For example, the first distance D1, the second distance D2, and the third distance D3 can be 2 μm, 6 μm, and 10 μm, respectively, 2 μm, 10 μm, and 18 μm, respectively, or 4 μm, 12 μm, 16 μm, respectively, and so on. That is, in this embodiment, the profile of the MEMS device structure 12 may substantially have a stepped feature greater than two steps. In the example that the stepped feature having three or more steps, the uppermost step among the stepped feature can have a distance between a bottom surface of the protrusion and a top surface of the covered block in a range from about 10 μm to about 30 μm to make the stepped feature obvious. The turbulence created by the protrusions (e.g., protrusions 120, 124, 130), whether created by the protrusion profile itself or by the large volume of liquid coolant in the enlarged chambers under these protrusions, the gradually changing profile of the MEMS device structure 12 may induce a relatively regular flow in the cooling tank. As a result, heat can be removed from the object to be cooled more effectively.

Moreover, the stepped feature can not only be present among different protrusions of the cap structure 106, but also among the regions of the support structure 104 that are not covered by the protrusions of the cap structure 106. For example, as shown in FIG. 4, in a three-step design, the support structure 104 may include a first region 171, a second region 172, and a third region 173, each having blocks with different heights. These blocks with different heights can be formed by using different patterning operations. That is, additional photomasks would be used for forming a greater height variation, and the cost would be increased accordingly. Therefore, in some of the embodiments, the number of steps is controlled to not exceed three or four, and as aforementioned, the distance between the bottom surface of the protrusion and the top surface of the covered block is in a range from about 10 μm to about 30 μm to make the stepped feature obvious. Additionally, since the blocks that are not spanned by the protrusions and are not used to support the protrusions (e.g., the blocks 112C labeled in FIG. 4A) do not need to be controlled to be shorter in order to enlarge the chamber, these blocks can be substantially the same height as one of the adjacent blocks, as these blocks and the adjacent blocks are fabricated in the same patterning operation.

In some embodiments, the height of the frame structure 102 at two opposite sides thereof can be different. For example, as shown in FIG. 4A, a height H3 of the frame structure 102 (e.g., the inner frame 102B) in proximity to the third cap 128 is greater than a height H4 of the frame structure 102 (e.g., the inner frame 102B) in proximity to the first cap 116. In some embodiments, heights of the outer frame 102A may be different from each other. For example, the height of the outer frame 102A in proximity to the third cap 128 is greater than the height of the outer frame 102A in proximity to the first cap 116.

In some alternative embodiments, as shown in FIG. 4B, the profile of a MEMS device structure 14 may have an uneven feature due to randomly arranged protrusions of varying heights. For example, the third cap 128 can be located between the first cap 116 and the second cap 118. In this embodiment, even without generating a relatively regular flow in the cooling tank by arranging the caps of different heights in a gradual manner, the turbulence created by the protrusion profile itself (e.g., protrusions 120, 124, 130) and/or by the large volume of liquid coolant in the enlarged chambers under these protrusions may still enhance the heat removal capability compared to a comparative embodiment that does not employ a MEMS device structure with an uneven feature or enlarged chambers.

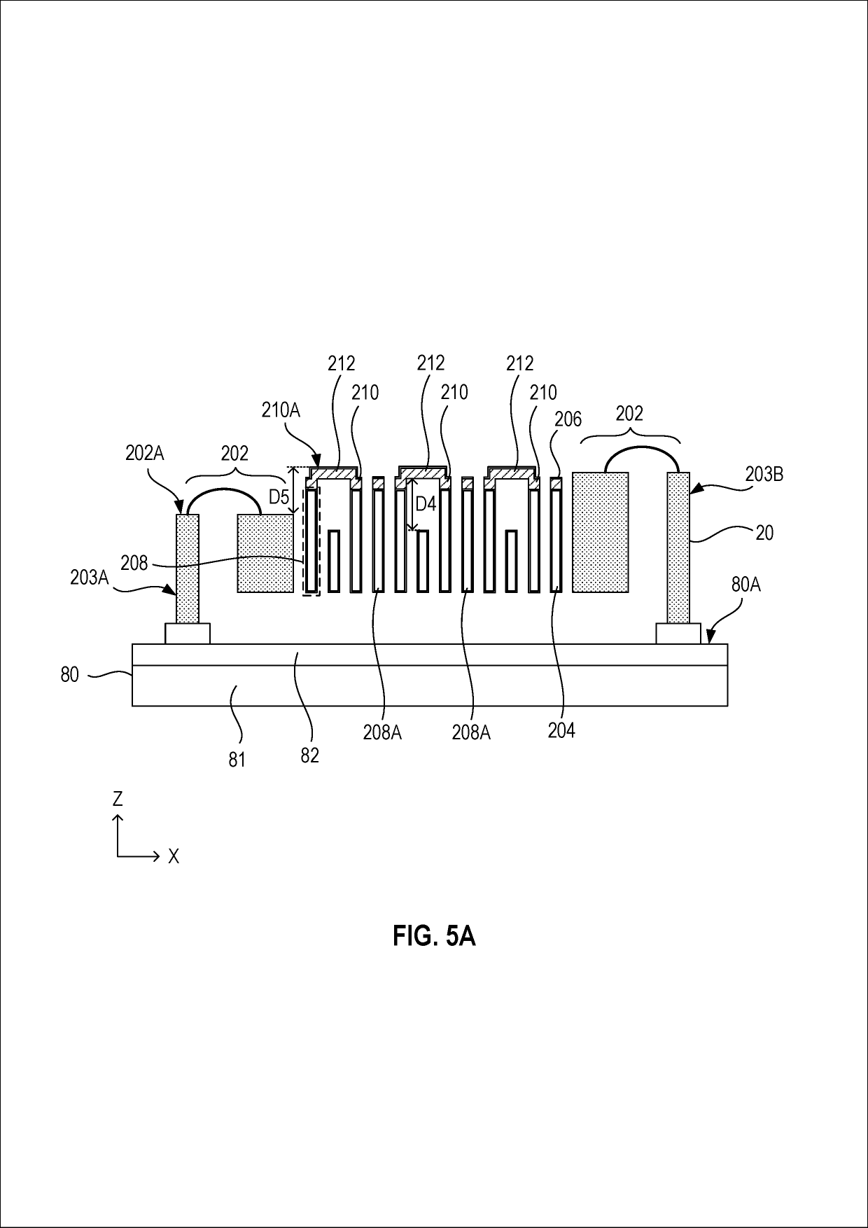

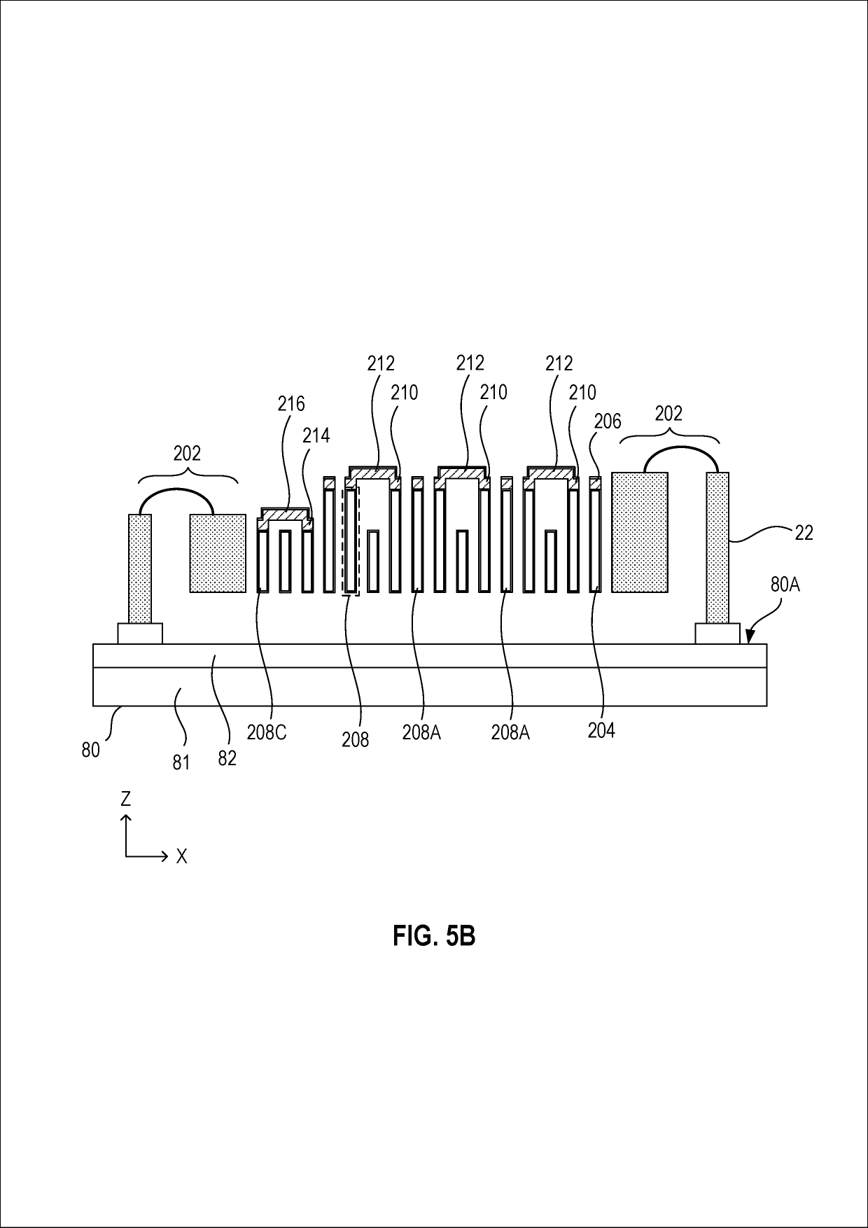

Referring to FIG. 5A, in some embodiments, the MEMS device structure 20 may include a frame structure 202, a support structure 204, and a cap structure 206. The features of frame structure 202 and the support structure 204 can be similar to those of the frame structure 102 and the support structure 104 of the MEMS device structure 10 disclosed in FIG. 1. In the embodiment shown in FIG. 5A, the support structure 204 includes a plurality of blocks 208, and the cap structure 206 includes a plurality of caps 210 disposed over the support structure 204, and a protrusion 212 of each of the plurality of cap 210 spans at least one of the block 208 of the support structure 204. An upper surface 210A of the plurality of caps 210 is higher than an upper surface 202A of a first side of the frame structure 202.

In the embodiment shown in FIG. 5A, the protrusions 212 of the plurality of caps 210 are substantially aligned with each other, for example, the upper surface 210A of the plurality of caps 210 (i.e., the upper surface the protrusions) are substantially coplanar to each other. Compared to the embodiment shown in FIGS. 1, 4A, or 4B, the profile of the MEMS device structure 20 in the embodiment shown in FIG. 5A can be free from having an uneven feature, as all the protrusions are elevated. In other words, the embodiment shown in FIG. 5A includes a plurality of protrusions on the cap, elevated by the tall support structure. These protrusions primarily serve to create larger chambers under them, allowing a greater volume of liquid coolant to be pumped out during electrode vibrations. Accordingly, the distance differences (e.g., the difference between distances D1 and D2 and/or the difference between distances D1, D2, and D3 in previous embodiments) between the protrusions of different caps and the blocks of the support structure, as illustrated in previous embodiments, can be eliminated.

In some embodiments, a distance D4 between the protrusion 212 (i.e., a bottom surface of the protrusion 212) of each of the plurality of caps 210 and the block 208 (i.e., a top surface of the block 208) of the support structure 204 spanned by the protrusions 212 is in a range from about 10 μm to about 30 μm. The lower limit of the range of distance D4 is associated with the ability to pump out a sufficient volume of liquid coolant during electrode vibrations. Therefore, the lower limit of this distance is greater than that in the embodiments which also take into account the uneven feature of the MEMS device structure.

In some embodiments, the frame structure 202 includes a first side 203A and a second side 203B opposite to the first side 203A, and a height of the second side 203B is greater than a height of the first side 203A. For example, the height of the frame structure 202 on the second side 203B is greater than the height of the frame structure 202 on the first side 203A. In some embodiments, a height difference D5 between the frame structure 202 (i.e., an upper surface of the frame structure 202) and an upper surface of the bonded caps 210 may create an uneven feature of the MEMS device structure 20 and help the creation of turbulence in the cooling tank.

In some embodiments, each of the plurality of caps 210 is bonded over a pair of blocks 208 of the support structure 204, and a height of the pair of blocks 208 of the support structure 204 is greater than a height of the block 208 of the support structure 204 spanned by the caps 210. Moreover, in some embodiments, a block 208A of the support structure 204 can be located between each of two adjacent caps 210 having protrusion 212, a height of the block 208A can be identical to a height of the blocks 208 bonded to the caps 210 having protrusion 212.

In other words, the comb-typed electrodes (i.e., the cap structures over the comb-typed support structures) in some embodiments of the present disclosure may feature a plurality of protrusions on a first set of electrodes, spanning over an interdigitated second set of electrodes. For instance, as shown in FIG. 5A, the blocks 208 of the support structure 204, which are bonded to the caps 210 having protrusions 212, can belong to a first set of electrodes. The block 208A and the block 208 spanned by the protrusion 212 can belong to a second set of electrodes, while the first and second sets of electrodes are arranged in an interdigitated manner. In some embodiments, after the interdigitated fingers of the support structure 204 are formed, some of the fingers of the support structure 204 can be further etched to decrease their height. These shortened parts of the fingers are referred to as block 208A, which can be spanned by the protrusions 212 of the cap 210 to create large chambers under the protrusions 212.

Referring to FIG. 5B, in some alternative embodiments, a MEMS device structure 22 may further include one or more caps 214 disposed over the support structure 204, with a protrusion 216 of the cap 214 spanning at least one block 208 of the support structure 204. The cap 214 can be called a short cap since it is substantially not elevated, as the height of the blocks (e.g., the blocks 208C) of the support structure 204 bonded to it is substantially identical to the height of the blocks of the support structure 204 covered by the protrusions 212. In some embodiments, the distance between the protrusion 216 of the cap 214 and the block 208 of the support structure 204 spanned by the protrusion 216 is in the range of about 2 μm to about 4 μm. Furthermore, when employing the MEMS device structure 22 on the semiconductor structure 80, the arrangement of protrusions 212 (i.e., from elevated caps) and protrusions 216 (i.e., from non-elevated caps) can be tailored to meet the cooling requirements of different regions or areas of the semiconductor structure 80.

In some embodiments, the object to be cooled can be a semiconductor wafer including 3DIC or other packaging structures. In some embodiments, the object to be cooled can be dies, chips, modules, etc., disposed over a substrate (e.g., PCB), such as the semiconductor structure 80 shown in previous embodiments. However, other embodiments of the present invention are not limited to these.

In some embodiments, the MEMS device structure disclosed in the present disclosure can be employed as a heat dissipation structure for the object to be cooled, such as the abovementioned examples.

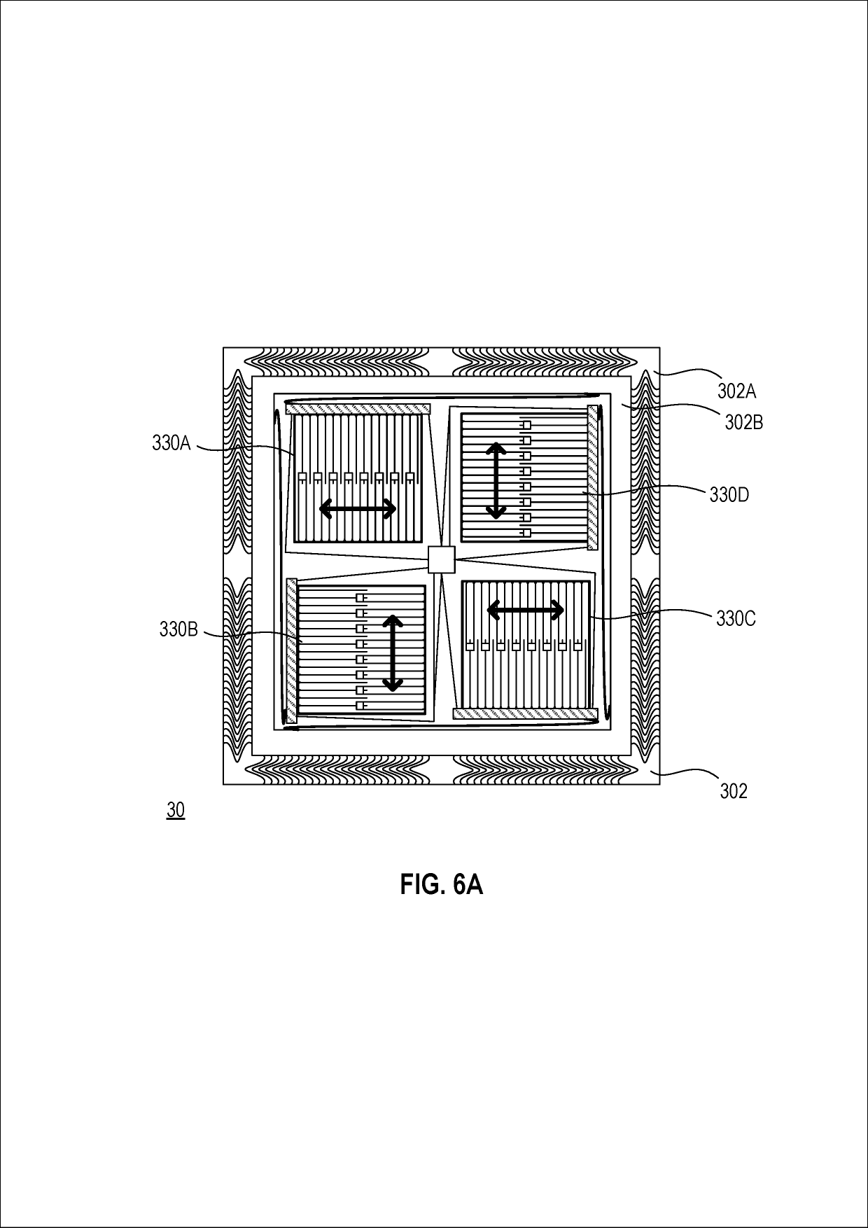

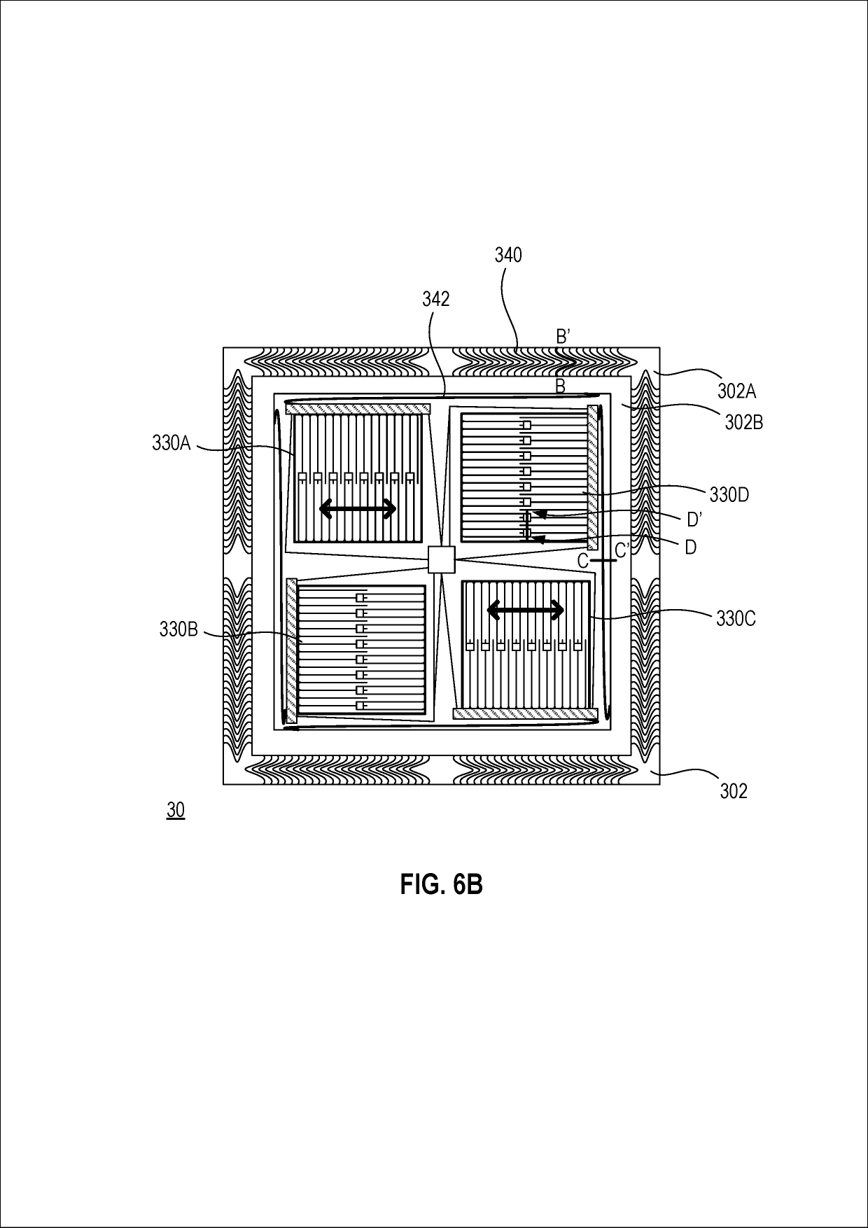

FIG. 6A illustrates a top view of a MEMS device structure 30 disposed over a semiconductor wafer, which is configured to enhance cooling efficiency applied to the semiconductor wafer. In some embodiments, within a frame structure 302 of the MEMS device structure 30, a plurality of drive combs (e.g., the drive combs 330A, 330B, 330C, and 330D) are distributed and driven in different vibration directions (e.g., the directions indicated by double arrows). For example, as shown in FIG. 6A, each drive comb may vibrate in a direction different from that of adjacent drive combs. By arranging these drive combs in this manner, the flow of liquid coolant generated or strengthened by the vibrations may create greater turbulence or establish circulation patterns conducive to accelerating cooling, thereby improving cooling efficiency within the cooling tank.

In some embodiments, each drive comb can be controlled to vibrate or remain stationary, depending on the cooling efficiency requirements. For instance, in cases where only certain regions of the semiconductor wafer need to be cooled, one or more selected drive comb(s) can be activated to enhance cooling efficiency within the selected regions. As shown in FIG. 6B, for example, the drive combs 330A and 330C are vibrating, while the drive combs 330B and 330D remain in a fixed position.

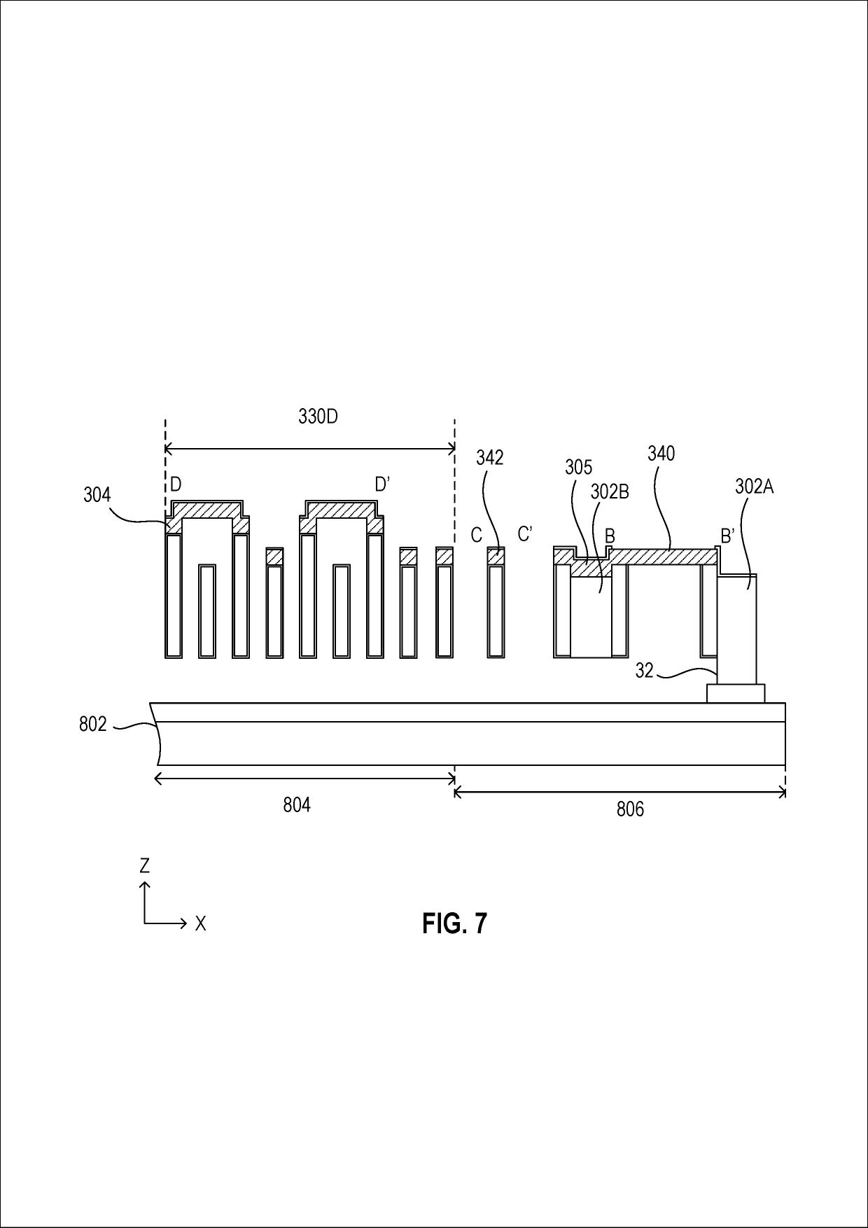

FIG. 7 is a cross-sectional view of a MEMS device structure 32 according to some embodiments of the present disclosure. FIG. 7 illustrates some of the features of the MEMS device structure along the lines depicted in FIG. 6B (e.g., a line BB’ for a first spring structure, a line CC’ for a second spring structure, and a line DD’ for metal caps in a cap structure). The present disclosure is not limited to the proportions shown in these figures. In some embodiments, as shown in FIG. 7, a cap structure 304 of the MEMS device structure 32 includes a plurality of first spring structures 340 in proximity to one side of the frame structure 302. In some embodiments, the first spring structures 340 are located between an outer frame 302A and an inner frame 302B of the frame structure 302. In some embodiments, the material of the first spring structures 340 includes metal.

In some embodiments, the first spring structures 340 are configured to provide a suspension and restoring mechanism since they connect the outer frame 302A of the frame structure 302 to a metal pad 305 over the inner frame 302B. The outer frame 302A of the frame structure 302 is configured to be fixed and positioned over the semiconductor wafer.

In some embodiments, the cap structure 304 of the MEMS device structure 32 further includes a plurality of second spring structures 342 (e.g., four second spring structures 342). Each of the second spring structures 342 may connect to one of the drive combs (e.g., the drive combs 330A, 330B, 330C, and 330D in FIGS. 6A and 6B), allowing them to vibrate independently. Therefore, the second spring structures 342 are located between the inner frame 302B and the drive combs.

Regarding the drive combs, FIG. 7 uses drive comb 330D as an example. However, drive comb 330D may have the same features as the cap structures previously shown in the embodiments in FIGS. 1, 4A, 4B, 5A or other reasonable alternatives that may enhance cooling efficiency. These details are omitted here for brevity.

By using the MEMS device structures disclosed in the present disclosure as a heat dissipation structure, the object bonded to the MEMS device structures, such as a semiconductor wafer or a substrate 802, may have a device region 804 and a peripheral region 806 adjacent to the device region 804. In some embodiments, the components for cooling by the MEMS device structure are positioned within the device region 804. In some embodiments, the protrusions of the caps in the cap structure 304 are positioned projectively over the device region 804 of the substrate 802 to efficiently dissipate heat from the device region 804. The peripheral region 806 of the substrate 802 may be an area with relatively lower cooling requirements. In some embodiments, the first spring structure 340 and/or the second spring structure 342 are positioned over the peripheral region 806 of the substrate 802.

In some embodiments, the semiconductor wafer, or the substrate 802 bonded to the MEMS device structures may include a plurality of semiconductor die structures. For instance, in a 12-inch semiconductor wafer, there can be more than about 700 semiconductor components. In some embodiments, more than about 700 MEMS device structures can be bonded to the substrate 802. In some embodiments, a single MEMS device structure may cover two or more semiconductor components; therefore, the number of MEMS device structures used for a single substrate 802 can be lower than the number of semiconductor components with a similar dissipation target in the substrate 802.

The MEMS device structure in some embodiments of the present disclosure can be formed under a typical manufacturing process of a MEMS structure, wherein one or more portions of the comb-typed electrodes are elevated. That is, the formation of the MEMS device structure in some embodiments of the present disclosure is compatible with current MEMS manufacturing process. By using additional photomasks and patterning operations, a height difference can be created in the comb-type electrodes in different regions. In some embodiments, after multiple patterning operations form the support structure with height differences, the first oxide layer can be formed on the surface of the support structure. Then, a portion of the cap structure is deposited above the support structure. One or more protrusions can further be formed above the portion of the cap structure, and each of the protrusions may span across at least one finger-like structure in the support structure. In the cross-sectional view, these protrusions can be seen to span at least one block of the support structure. In some embodiments, the protrusion can be bonded to the previously deposited cap structure using bonding techniques, spanning at least one block of the support structure, but other embodiments of the present invention are not limited to this. Moreover, to strengthen the physical structure of the cap structure, the second oxide layer can then be deposited on the surface of the cap structure.

In one exemplary aspect, a micro-electro mechanical system (MEMS) device structure is provided. The MEMS device structure includes a frame structure, a support structure, and a cap structure. The frame structure defines a region. The support structure is coupled with the frame structure. The support structure includes a plurality of blocks laterally arranged within the region from a cross-sectional view perspective. The cap structure is over the support structure. The cap structure includes a first cap disposed over the support structure and a protrusion of the first cap spans at least a first block of the support structure; and a second cap disposed over the support structure and a protrusion of the second cap spans at least a second block of the support structure. A first distance between a bottom surface of the protrusion of the first cap and a top surface of the first block of the support structure is different from a second distance between a bottom surface of the protrusion of the second cap and a top surface of the second block of the support structure.

In another exemplary aspect, a micro-electro mechanical system (MEMS) device structure is provided. The MEMS device structure includes a frame structure, a support structure, and a cap structure. The frame structure has a first side and a second side opposite to the first side, and a height of the second side is greater than a height of the first side. The support structure is coupled with the frame structure, the support structure includes a plurality of blocks within the first side and the second side of the frame structure from a cross-sectional view perspective. The cap structure is over the support structure. The cap structure includes a plurality of caps disposed over the support structure, and a protrusion of each of the plurality of cap spans at least one of the blocks of the support structure. An upper surface of the plurality of caps is higher than an upper surface of the first side of the frame structure.

In yet another exemplary aspect, a semiconductor structure is provided. The semiconductor structure includes a substrate and a heat dissipation structure over the substrate. The heat dissipation structure includes an outer frame structure, an inner frame structure, a support structure, and a cap structure. The outer frame structure is disposed on the substrate. The inner frame structure is adjacent to the outer frame structure. The support structure has a plurality of blocks suspended over the substrate from a cross-sectional view perspective. The cap structure is over the support structure. The cap structure includes a first protrusion spans at least one of the plurality of blocks of the support structure. A distance between a bottom surface of the first protrusion and a top surface of the at least one of the plurality of blocks spanned by the first protrusion is in a range from about 10 μm to about 30 μm.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A micro-electro mechanical system (MEMS) device structure, comprising:
a frame structure defining a region;
a support structure coupled with the frame structure, the support structure comprises a plurality of blocks laterally arranged within the region from a cross-sectional view perspective; and
a cap structure over the support structure, comprising:
a first cap disposed over the support structure and a protrusion of the first cap spans at least a first block of the support structure; and
a second cap disposed over the support structure and a protrusion of the second cap spans at least a second block of the support structure,
wherein a first distance between a bottom surface of the protrusion of the first cap and a top surface of the first block of the support structure is different from a second distance between a bottom surface of the protrusion of the second cap and a top surface of the second block of the support structure.

2. The MEMS device structure of claim 1, wherein the second distance between the bottom surface of the protrusion of the second cap and the top surface of the second block of the support structure is in a range from about 6 μm to about 30 μm.

3. The MEMS device structure of claim 1, wherein an upper surface of the protrusion of the second cap is higher than an upper surface of the protrusion of the first cap.

4. The MEMS device structure of claim 1, wherein the first cap is bonded to a first pair of blocks of the support structure, and the second cap is bonded to a second pair of blocks of the support structure.

5. The MEMS device structure of claim 4, wherein a height of the first pair of blocks of the support structure is less than a height of the second pair of blocks of the support structure.

6. The MEMS device structure of claim 1, wherein the cap structure further comprises a third cap disposed over the support structure and a protrusion of the third cap spans at least a third block of the support structure, and a third distance between a bottom surface of the protrusion of the third cap and a top surface of the third block of the support structure is greater than the second distance between the bottom surface of the protrusion of the second cap and the top surface of the second block of the support structure.

7. The MEMS device structure of claim 6, wherein the first distance, the second distance, and the third distance are arranged to be increased gradually between two sides of the region.

8. The MEMS device structure of claim 6, wherein a height of the frame structure in proximity to the third cap is greater than a height of the frame structure in proximity to the first cap.

9. A micro-electro mechanical system (MEMS) device structure, comprising:
a frame structure having a first side and a second side opposite to the first side, and a height of the second side is greater than a height of the first side;
a support structure coupled with the frame structure, the support structure comprises a plurality of blocks within the first side and the second side of the frame structure from a cross-sectional view perspective; and
a cap structure over the support structure, comprising:
a plurality of caps disposed over the support structure, and a protrusion of each of the plurality of cap spans at least one of the blocks of the support structure,
wherein an upper surface of the plurality of caps is higher than an upper surface of the first side of the frame structure.

10. The MEMS device structure of claim 9, wherein a distance between a bottom surface of the protrusion of each of the plurality of caps and a top surface of the block of the support structure spanned by the protrusions is in a range from about 10 μm to about 30 μm.

11. The MEMS device structure of claim 9, wherein each of the plurality of caps is bonded over a pair of blocks of the support structure, and a height of the pair of blocks of the support structure is greater than a height of the block of the support structure spanned by the caps.

12. The MEMS device structure of claim 9, wherein the cap structure further comprises a spring structure in proximity to the first side or the second side of the frame structure.

13. The MEMS device structure of claim 9, further comprising a plurality of flow channels comprising a space between the caps and the blocks of the support structure spanned by the caps, and each of the flow channels are connected with a space between two adjacent blocks of the support structure.

14. The MEMS device structure of claim 9, wherein the cap structure further comprises at least a short cap disposed over the support structure, an upper surface of the short cap is lower than the upper surface of the plurality of caps.

15. A semiconductor structure, comprising:
a substrate; and
a heat dissipation structure over the substrate, comprising:
an outer frame structure disposed on the substrate;
an inner frame structure adjacent to the outer frame structure;
a support structure having a plurality of blocks suspended over the substrate from a cross-sectional view perspective; and
a cap structure over the support structure, the cap structure comprises a first protrusion spans at least one of the plurality of blocks of the support structure,
wherein a distance between a bottom surface of the first protrusion and a top surface of the at least one of the plurality of blocks spanned by the first protrusion is in a range from about 10 μm to about 30 μm.

16. The semiconductor structure of claim 15, wherein the cap structure further comprises a second protrusion spans at least one of the plurality of blocks of the support structure, and a volume of a first flow channel substantially enclosed by the first protrusion and the support structure is different from a volume of a second flow channel substantially enclosed by the second protrusion and the support structure.

17. The semiconductor structure of claim 16, wherein a width of the first protrusion is substantially identical to a width of the second protrusion.

18. The semiconductor structure of claim 15, wherein the substrate comprises:
a device region; and
a peripheral region adjacent to the device region, and wherein the first protrusion is projectively over the device region of the substrate.

19. The semiconductor structure of claim 18, wherein the cap structure further comprises a plurality of spring structures over the peripheral region of the substrate.

20. The semiconductor structure of claim 15, wherein one of the block spanned by the first protrusion and the two of the blocks bonded to the cap structure belongs to different comb electrodes of a MEMS structure.
